(19) United States
(12) Patent Application Publication
(10) Pub. No.: US 2025/0220987 A1
(43) Pub. Date: Jul. 3, 2025

(54) CHANNEL DEPOPULATION USING PLACEHOLDER DIELECTIRIC

(71) Applicant: International Business Machines Corporation, Armonk, NY (US)

(72) Inventors: Liqiao Qin, Albany, NY (US); Tao Li, Slingerlands, NY (US); Ruilong Xie, Niskayuna, NY (US); Julien Frougier, Albany, NY (US)

(21) Appl. No.: 18/399,002

(22) Filed: Dec. 28, 2023

(51) Int. Cl. H01L 29/06; H01L 29/08; H01L 29/423; H01L 29/66; H01L 29/775; H01L 29/786

(52) U.S. Cl. CPC H10D 62/116; H10D 30/014; H10D 30/031; H10D 30/43; H10D 30/6757; H10D 62/151; H10D 64/018; H10D 30/6735; H10D 62/121

(57) ABSTRACT

A semiconductor device that includes a first plurality of stacked channel layers, and a second plurality of stacked channel layers. The semiconductor device further includes a placeholder disposed between the first plurality of stacked channels and the second plurality of stacked channel layers, wherein sidewalls of the placeholder directly contact sidewalls of at least one channel in the first plurality of stacked channels and at least one channel in the second plurality of stacked channels.

### BACKGROUND

The present invention generally relates to semiconductor devices, and more particularly to lower power consumption semiconductor structures and high performance semiconductor devices within a same device structure.

Field effect transistors (FETs) are widely used in the electronics industry for switching, amplification, filtering and other tasks related to both analog and digital electrical signals. Most common among these are metal oxide semiconductor field effect transistors (MOSFET or MOS), in which a gate structure is energized to create an electric field in an underlying channel region of a semiconductor body, by which electrons are allowed to travel through the channel between a source region and a drain region of the semiconductor body.

Nanosheet devices are a type of FET that provides for increased device integration and improved scaling. However, when co-integrating different types of semiconductor devices in the same device structure, the energy consumption from the different types of devices can become a concern. Some devices employ voltage scaling techniques to decrease the energy consumption.

However, most voltage scaling techniques can make the various semiconductor devices more susceptible to process and/or dopant variations that can cause the devices to not function properly.

Accordingly, solutions are needed to effectively co-integrate high performance semiconductor devices and low power consumption semiconductor devices in a same device structure.

### SUMMARY

In accordance with some embodiments of the present invention, semiconductor device structures are described herein that can overcome the above deficiencies in integrating low power consumption semiconductor devices and high performance semiconductor devices on the same device structure without requiring significantly different device processing for the different types of devices. More particularly, for low power semiconductor devices having vertically stacked channel regions, at least one of the channel layers for the low power consumption devices can be depopulated by contacting the channel layer with a placeholder, e.g., a placeholder of a dielectric material. By contacting the ends of a channel layer with the placeholder, the channel layer is obstructed from being contacted by a source/drain region. A high performance semiconductor device having a vertically stacked channel region may be integrated with the aforementioned low power consumption device with minimal processing by adjusting the height of the placeholder for each of the different types of devices. More particularly, the placeholder in the high performance semiconductor device will have a lesser height than the placeholder for the low power consumption semiconductor device. By employing a placeholder having a lesser height in the high performance semiconductor devices, a lesser number of stacked channel layers in the high performance device will be obstructed from contacting source/drain regions when compared to a similarly processed low power consumption device having placeholders with a greater height. For a high performance semiconductor device including vertically stacked channel regions, the high performance semiconductor device can have a greater number of channel layers in contact with the source/drain regions than the low power consumption semiconductor device.

In an embodiment, a semiconductor device is provided that includes a first plurality of stacked channel layers; and a second plurality of stacked channel layers. In one embodiment, a placeholder is disposed between the first plurality of stacked channels and the second plurality of stacked channel layers. In some embodiments, sidewalls of the placeholder directly contact sidewalls of at least one channel in the first plurality of stacked channels, and at least one channel in the second plurality of stacked channels. In some examples, this embodiment can provide two low power consumption semiconductor devices on a same device substrate.

In some embodiments, the placeholder is composed of a dielectric core having a liner present on exterior surfaces. In some embodiments, the liner of the placeholder has a composition selected from the group consisting of SiN, SiBCN, SiC, SiOC, SiOCN, AlNₓ, AlOₓ and combinations thereof. In some embodiments, the device includes source/drain regions atop the placeholder to each of the first plurality of stacked channels and the second plurality of stacked channels. In some embodiments, the at least one of the first plurality of stacked channel layers and the second plurality of stacked channel layers includes nanosheets.

In another embodiment, a semiconductor device is provided that includes a source/drain region disposed between vertically stacked channel regions; and a placeholder disposed within a portion of the source/drain region and interposed between at least one channel region of the vertically stacked channel regions and the source/drain region.

In an embodiment, the placeholder is comprised of a dielectric core having a liner present on exterior surfaces. The liner has a composition selected from the group consisting of SiN, SiBCN, SiC, SiOC, SiOCN, AlNₓ, AlOₓ and combinations thereof. In an embodiment, the vertically stacked channel regions of the semiconductor device include nanosheets. In an embodiment, a gate structure is present on the vertically stacked channel regions. In one embodiment, the gate structure is a gate all around gate structure.

### BRIEF DESCRIPTION OF DRAWINGS

The disclosure will provide details in the following description of preferred embodiments with reference to the following figures wherein:

FIG. 1 is a top down view of a semiconductor device with channel depopulation provided by placeholders in combination with a backside power distribution network, in which the top down view illustrates the cross-section line identified by X-X for each of the side-cross sectional figures provided herein, in accordance with an embodiment of the present invention;

FIG. 2 is a side cross-sectional view of a high performance device with middle of the line contacts along section line X-X of FIG. 1, in accordance with an embodiment of the present invention;

FIG. 3 is a side cross-sectional view of a high performance device with a backside contact and a front side middle of the line contact along section line X-X of FIG. 1, in accordance with an embodiment of the present invention;

FIG. 4 is a side cross-sectional view of a low power consumption device with a backside contact and a frontside middle of the line contact along section line X-X of FIG. 1, in accordance with an embodiment of the present invention;

FIG. 5 is a side cross-sectional view of a low power consumption device with middle of the line contacts along section line X-X of FIG. 1, in accordance with an embodiment of the present invention;

FIG. 6 is a side cross-sectional view along section line X-X of an initial semiconductor device structure following front end of the line processing, middle of the line processing, back end of the line processing, and wafer bonding, in accordance with an embodiment of the present invention;

FIG. 7 is a side cross-sectional view along section line X-X of the structure depicted in FIG. 6 being further processed to provide a dielectric fill and recess step that will ultimately depopulate the bottom nanosheet channel of a lower power consumption device, in accordance with an embodiment of the present invention;

FIG. 8 is a side cross-sectional view along section line X-X that illustrates patterning for removing portions of a dielectric placeholder from a low power consumption device with a backside contact, in accordance with an embodiment of the present invention;

FIG. 9 is a side cross-sectional view along section line X-X that illustrates patterning for removing portions of a placeholder having a dielectric material from a low power device with frontside contacts to a wiring in a middle of the line wiring level, in accordance with an embodiment of the present invention;

FIG. 10 is a side cross-sectional view along section line X-X that illustrates removing portions of a placeholder having a dielectric material from a high performance device with a backside contact, in accordance with an embodiment of the present invention;

FIG. 11 is a side cross-sectional view along section line X-X that illustrates removing portions of a placeholder of a dielectric material from a low power consumption device with a backside contact, in accordance with an embodiment of the present invention;

FIG. 12 is a side cross-sectional view along section line X-X that illustrates removing portions of a placeholder of a dielectric material from a low power consumption device with frontside contacts to a wiring in a middle of the line wiring level, in accordance with an embodiment of the present invention;

FIG. 13 is a side cross-sectional view along section line X-X that illustrates forming a placeholder and source regions and drain region for a high performance device with a backside contact, in accordance with an embodiment of the present invention;

FIG. 14 is a side cross-sectional view along section line X-X that illustrates forming a placeholder fill and forming a source region and a drain region for a low power device with a backside contact, in accordance with an embodiment of the present invention;

FIG. 15 is a side cross-sectional view along section line X-X that illustrates forming source and drain regions for a low power device with frontside contacts to a wiring in a middle of the line wiring level, in accordance with an embodiment of the present invention;

FIG. 16 is a side cross-sectional view along section line X-X that illustrates a resulting structure following a replacement metal gate structure, middle of the line processing, back end of the line processing and bonding a carrier wafer for a high performance device having front side contacts with wiring in a middle of the line processing level, in accordance with an embodiment of the present invention;

FIG. 17 is a side cross-sectional view along section line X-X that illustrates a resulting structure following a replacement metal gate structure, middle of the line processing, back end of the line processing and bonding a carrier wafer for a high performance device with a backside contact, in accordance with an embodiment of the present invention;

FIG. 18 is a side cross-sectional view along section line X-X that illustrates a resulting structure following a replacement metal gate structure, middle of the line processing, back end of the line processing and bonding a carrier wafer for a low power device with a backside contact, in accordance with an embodiment of the present invention;

FIG. 19 is a side cross-sectional view along section line X-X that illustrates a resulting structure following a replacement metal gate structure, middle of the line processing, back end of the line processing and bonding a carrier wafer for a low power device with frontside contacts to a wiring in a middle of the line wiring level, in accordance with an embodiment of the present invention;

FIG. 20 is a side cross-sectional view along section line X-X that illustrates a resulting structure following a replacement metal gate structure, middle of the line processing, back end of the line processing and bonding a carrier wafer for a high performance semiconductor device having front side contacts with wiring in a middle of the line processing level, in accordance with an embodiment of the present invention;

FIG. 21 is a side cross-sectional view along section line X-X that illustrates a removing the substrate from a high performance semiconductor device with a backside contact, in accordance with an embodiment of the present invention;

FIG. 22 is a side cross-sectional view along section line X-X that illustrates removing the substrate a low power consumption semiconductor device with a backside contact, in accordance with an embodiment of the present invention;

FIG. 23 is a side cross-sectional view along section line X-X that illustrates removing the substrate from a low power consumption semiconductor device with frontside contacts to a wiring in a middle of the line wiring level, in accordance with an embodiment of the present invention;

FIG. 24 is a side cross-sectional view along section line X-X that illustrates forming an opening for a backside contact to a high performance semiconductor device with a backside contact, in accordance with an embodiment of the present invention;

FIG. 25 is a side cross-sectional view along section line X-X that illustrates forming an opening for a backside contact to a low power consumption semiconductor device with a backside contact, in accordance with an embodiment of the present invention.

### DETAILED DESCRIPTION

Detailed embodiments of the claimed methods and structures are described herein; however, it is to be understood that the embodiments described are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

The semiconductor device structures described herein can overcome difficulties in integrating low power consumption semiconductor devices and high performance semiconductor devices on a same device structure. In prior instances, in order to integrate high performance semiconductor devices with low power consumption semiconductor devices different device processing was employed for the different types of devices in order to meet the separate requirements for a low power consumption semiconductor device and a high performance semiconductor device.

In an embodiment, structures and methods can provide semiconductor devices including placeholder based channel depopulation. More particularly, in semiconductor devices employing vertically stacked channel layers, a placeholder filled with dielectric material can be used to obstruct at least one of the channel layers that is present in the stack from contacting a source/drain region. This results in a channel layer being depopulated. The height of the placeholder can be adjusted across the device during processing with minimal changes to the remainder of the device processing. For example, low power consumption devices can be processed to have greater height placeholders that contact at least one channel layer to depopulate the channel layer, while high performance semiconductor devices can be processed to have a lower height so that the source/drain regions present atop the placeholders can contact a greater number of channel layers in the stack. For the high performance semiconductor devices, the greater number of channel layers in the stack that contact the source/drain regions, the greater the device's performance. The methods and structures of the present disclosure are now described with reference to FIGS. 1-25.

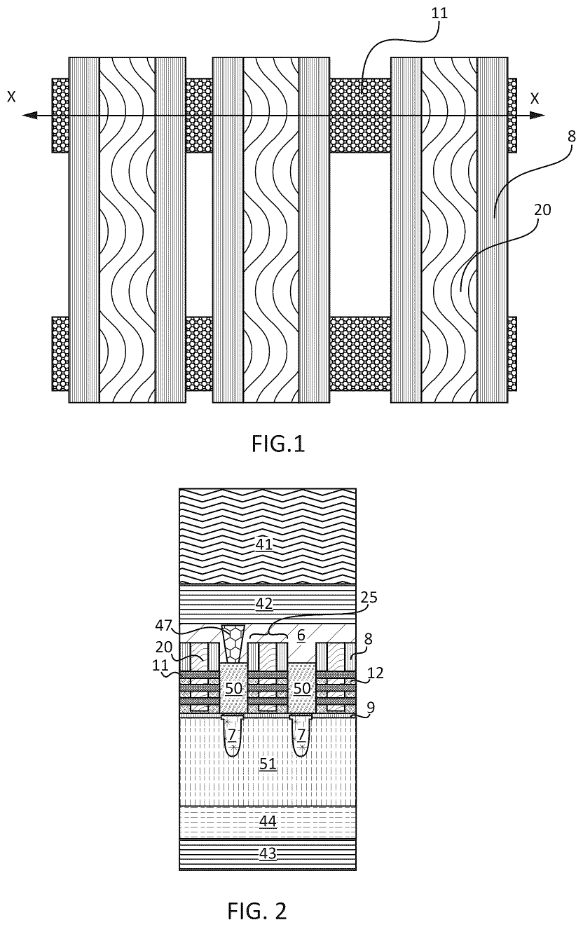

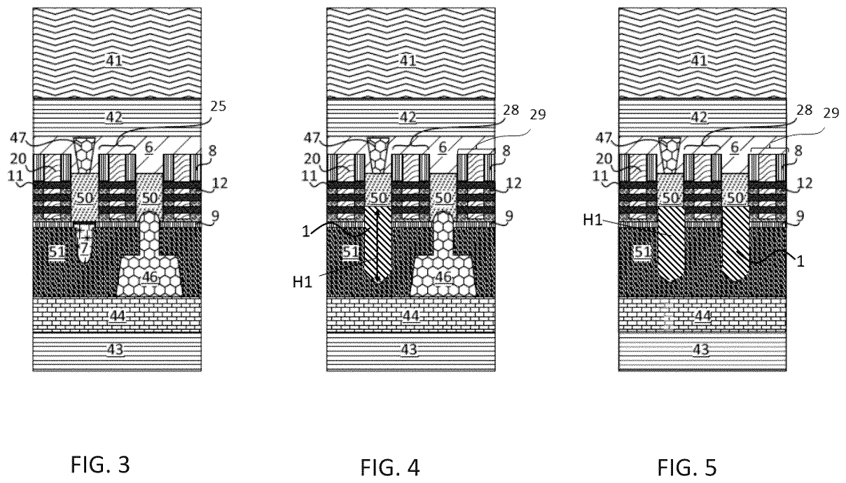

FIG. 1 is a top down view of semiconductor structure illustrating section line X-X. FIG. 2 is a side cross-sectional view of a high performance device with middle of the line contacts along section line X-X of FIG. 1. FIG. 3 is a side cross-sectional view of a high performance device with a backside contact and a front side middle of the line contact along section line X-X of FIG. 1. FIG. 4 is a side cross-sectional view of a low power consumption semiconductor device with a backside contact and a frontside middle of the line contact along section line X-X of FIG. 1. FIG. 5 is a side cross-sectional view of a low power consumption semiconductor device with middle of the line contacts along section line X-X of FIG. 1. Each of the cross sections illustrated in FIGS. 2, 3, 4 and 5 may be integrated into the same device structure simultaneously. Integrating the devices illustrated in FIGS. 2, 3, 4 and 5 into the same device structure can provide that high performance semiconductor devices and low power consumption semiconductor devices that are simultaneously integrated into the same device structure. For example, high performance semiconductor devices may be in a first region of the device structure, while low power consumption devices may be in a second region of the device structure.

FIG. 5 illustrates an embodiment of a semiconductor structure that includes a first semiconductor device having first channels 28, and a second semiconductor device having second channels 29. The first channels 28 and the second channels 29 include a plurality of nanosheets 11, in which the nanosheets 11 provide the channel regions for the semiconductor devices. A placeholder 1 is disposed between the first channels 28 and the second channels 29. The sidewalls of the placeholder 1 directly contact sidewalls of the at least one channel in the first channels 28 and at least one channel in the second channels 29. In the embodiment depicted in FIG. 5, the height H1 of the placeholder 1 contacts at least one nanosheet 11 in the first channels 28 and second channels 29 to depopulate at least one channel region. This is an embodiment of low power consumption semiconductor devices. More particularly, the example depicted in FIG. 5 provides two low power consumption semiconductor devices. A first low power consumption device includes the first channels 28 and a second low power consumption device includes second channels 29.

Still referring to FIG. 5, the placeholder 1 may include a dielectric core. In some embodiments, the placeholder 1 can further include a liner 54. The liner 54 can be presented on the exterior surfaces of the dielectric core. In some examples, a first side of the liner 54 is in direct contact with the at least one nanosheet 11 that provides the channel that is depopulated, and a second side of the liner 54 is in direct contact with the dielectric core of the placeholder 1. In one example, the liner 54 has the composition of a dielectric material. The dielectric material may be selected from SiN, SiBCN, SiC, SiOC, SiOCN, AlNx, AlOx and combinations thereof.

Still referring to FIG. 5, in one embodiment, a semiconductor device is provided that includes a source/drain region 50 disposed between the first channels 28 and second channels 29 that are vertically stacked. In one embodiment, the placeholder 1 is disposed within a portion of the source/drain region 50 and interposed between the first channels 28 and the source/drain region 50.

In some embodiments, the placeholder 1 that produces the depopulated channel is present under the source/drain regions 50 of the device. In some embodiments, the placeholder 1 may be aligned, e.g., self-aligned, with the source/drain regions 50. The source/drain regions 50 are directly atop the placeholder 1, and the source/drain regions 50 has sidewalls aligned with sidewalls of the placeholder 1.

In the embodiment depicted in FIG. 5, the source/drain regions 50 are contacted electrically by a frontside contact 47 to metal lines in a back end of the line processing level 42. The frontside contact 47 may be formed using middle of the line processing. The frontside contact 47 may be referred to as a middle of the line contact. In the embodiment that is depicted in FIG. 5, there is no backside contacts.

FIG. 4 illustrates another embodiment of a low power consumption semiconductor device that includes depopulated channel regions that are produced by contacting a channel layer with a placeholder 1. Similar to the embodiment depicted in FIG. 5, the channel layers for the devices depicted in FIG. 4 may be nanosheets 11. The embodiment depicted in FIG. 4 is similar to the embodiment that is depicted in FIG. 5. However, the embodiment depicted in FIG. 4 includes a direct backside contact 46. In this embodiment, the source/drain region 50 that is overlying the placeholder 1 is electrically contacted by a frontside contact 47 to metal lines in a back end of the line processing level 42, and the source/drain region 50 that is not overlying the placeholder 1 is electrically contacted by a back side contact 46 to a buried power rail 44. The buried power rail 44 is in electrical communication with a back side power distribution network 43.

The low power consumption devices depicted in FIGS. 4 and 5 having depopulated channel regions produced by the placeholder 1 may be present in the same device structure with high performance devices that do not include depopulated channel regions. Examples of high performance devices that do not include the depopulated channel regions are depicted in FIGS. 2 and 3.

For example, in an embodiment, a low power consumption semiconductor device can be included in a first region of the device structure first channels 28 and a first placeholder 1 disposed adjacent to the first channels 28, as illustrated in FIGS. 4 and 5. In the low power consumption devices depicted in FIGS. 4 and 5, the height H1 of the placeholder 1 is sufficient enough to contact at least one first channel layer in the first channels 28. The low power consumption devices depicted in FIGS. 4 and 5 can be in a first region of the device structure.

High performance devices as illustrated in the cross sections depicted in FIGS. 2 and 3 can be in a second region of the same device structure that includes the low power consumption devices illustrated in the cross sections depicted in FIGS. 4 and 5. A high performance device has a greater number of active channel layers than a low power consumption device, which includes depopulated channels through contact with a first placeholder 1.

For example, in an embodiment, the second semiconductor device that includes a greater number of active channel layers than the first device in the first region can include stacked channel layers 25, and a second placeholder 7 disposed adjacent to the stacked channel layers 25. The second placeholder 7 has a second height that is less than the first height H1 of the first placeholder 1. The height of the second placeholder 7 provides that a number of channel layers 25 that is contacted by the second placeholder 7 is less than a number of first channel layers in the first channels 28 that is contacted by the first placeholder 1. The embodiments depicted in FIGS. 1-5 only illustrate the example in which a single nanosheet 11 of the first channels 28 is depopulated in the low power consumption devices depicted in FIGS. 4 and 5, and that none of the nanosheets 11 in the performance staked channel layers is depopulated in the high performance devices depicted in FIGS. 2 and 3. This is only one example, and it is not intended that the structures and methods described herein be limited to only this example. For example, more than one channel layer may be depopulated with the low power consumption devices, and some channel layers may be depopulated in the higher performance devices, so long as the number of channels depopulated in the high performance devices is less than the number of channels depopulated in the low power consumption devices.

In an embodiment, the first placeholder 1 for the low power consumption devices can have a different composition than the second placeholder 7. For example, the first placeholder 1 for the low power consumption devices depicted in FIGS. 4 and 5 can have a dielectric core. The dielectric core may be an oxide, nitride or an oxynitride material. For example, the first placeholder 1 for the low power consumption devices depicted in FIGS. 4 and 5 can further include a liner 54 present on exterior surfaces of the dielectric core. For example, the second placeholder 7 for the high performance devices depicted in FIGS. 2 and 3 may have the composition of an intrinsic semiconductor material. An intrinsic semiconductor material has dielectric properties. For example, an intrinsic semiconductor material may be a type IV semiconductor, such as silicon or germanium, which is not doped with n-type or p-type dopants to a concentration level that results in electrical conductivity. The second placeholder 7 can also have a smaller width than the first placeholder 1.

Referring to FIGS. 2 and 3, in some embodiments, the second placeholder 7 may be aligned, e.g., self-aligned, with the source/drain regions 50. More particularly, the second/drain regions 50 are directly atop the second placeholder 7, and the source/drain regions 50 have sidewalls aligned with sidewalls of the second placeholder 7.

FIG. 2 is an embodiment of a high performance semiconductor device with middle of the line contacts. The device depicted in FIG. 2 does not include depopulated channels. The middle of the line contacts are frontside contacts 47 that extend from a back end of the line processing level 42 that includes metal wiring therein. The front side contacts 47 extend from the wiring in the back end of the line processing level 42 to an upper surface the source/drain regions 50. In the embodiment depicted in FIG. 2, each of the source/drain regions 50 are present over a second placeholder 7.

FIG. 3 illustrates an embodiment of a high performance semiconductor device with a middle of the line contact and a backside contact 46. In the embodiment depicted in FIG. 3, the source/drain regions 50 that is overlying the second placeholder 7 is in electrical contact with a frontside contact 47 to wiring in a back end of the line processing level 42, and the source/drain region 50 that is not present over the second placeholder 7 is in electrical contact with a backside contact 46. The backside contact 46 is in electrical communication to a buried power rail 44. The buried power rail 44 is in electrical communication with a backside power distribution network 43.

Referring to FIGS. 1-5, each of the semiconductor devices employing the channel regions provided by the first channels 28, the second channels 29 and the plurality of performance stacked channel layers 25 may include a gate structure 20. A “gate structure” is a structure used to control output current (i.e., flow of carriers in the channel) of a semiconducting device, such as a field effect transistor (FET). The gate structure 20 can be provided by a high-k gate dielectric, and a metal gate conductor, which may be referred to as a high-k metal gate (HKMG). The gate structure 20 may be a gate all around (GAA) structure.

The term “gate all around (GAA)” denotes that the gate structure 20 that encloses the channel region from both a frontside and backside of the channel. In some embodiments, a conformal dielectric layer is formed on suspended channels of a multiple channel region device, such as a vertically stacked nanosheet or nanowire structure. Thereafter, a gate conductive is formed, in which a single gate structure may enclose a plurality of channel regions having the conformal gate dielectric present thereon. In some instances, the gate all around (GAA) structure may include a conformal gate dielectric layer (not shown) having the composition of a high-k gate dielectric material, and a gate conductor of an elemental metal (which may be referred to as a metal gate).

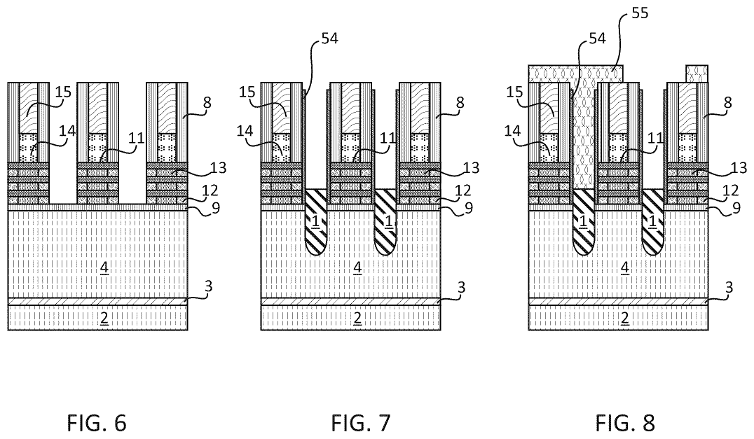

The structures illustrated in FIGS. 1-5 are now described in greater detail in accordance with the following embodiments of a method for forming a semiconductor device. It is noted that the following methods are only some examples of methods for forming the structures depicted in FIGS. 6-25.

FIG. 6 illustrates an embodiment of an initial structure that may be used in an embodiment of a method for forming the structures depicted in FIGS. 1-5.

FIG. 6 illustrates an embodiment following process steps such as forming stacks of nanosheets 11, nanosheet patterning and patterning of a replacement gate structure 15. Following formation of a replacement gate structure 15, a lower sacrificial sheet is removed from the patterned stack of nanosheets and replaced with a self-aligned substrate isolation layer 9. Thereafter, remaining sacrificial sheets in the patterned stack of nanosheets 11 are laterally etched, and the indentations formed by the lateral etch step are filled with a dielectric to provide an inner spacer 12. The inner spacer 12 supports the nanosheets 11 during later processing at which point the nanosheets 11 are suspended. The supporting structure depicted in FIG. 6 includes an upper semiconductor layer 4, etch stop layer 3 and substrate 2. The upper semiconductor layer 4, etch stop layer 3 and substrate 2 may each have the composition of semiconductor materials that are selected to provide for etch selectivity in accordance with the process flow described herein.

The stack of nanosheets 11 that is patterned may be provided by a type IV semiconductor material, such as silicon, silicon germanium, etc., or a type III-V semiconductor material, such as gallium arsenide. It is noted that any semiconductor material that may serve as the channel region of a field effect transistor may be employed for the nanosheets. It is noted that the stack of nanosheets may include sacrificial nanosheets 13. A first nanosheet composition may also be present in the stack, and removed to provide for spacing between suspended nanosheets 11. For example, a second sacrificial nanosheet composition that is present on the upper semiconductor layer 4 of the supporting structure may be substituted with the self-aligned substrate isolation layer 9. In some embodiments, nanosheets 11 ultimately provide the channel regions of the semiconductor devices, e.g., field effect transistors, and are also present in the stack.

Each of the layers in the nanosheets stack may have the composition of a type IV semiconductor composition. For example, the nanosheet stack may be a multilayered structure of nanosheets 11 which are ultimately processed to provide channel regions of the semiconductor device, while the first sacrificial nanosheets that are removed to provide suspended channels having a silicon germanium (SiGe30) layer having 30% germanium (Ge) content. The second sacrificial nanosheets may be removed and replaced with a dielectric material to provide the self-aligned substrate isolation layer 9.

The stack of the layered semiconductor materials for the nanosheets may be formed using a deposition process, such as epitaxial deposition. The thickness of each layer within the stack of the layered nanosheets may range from 1 nm to 30 nm. In another embodiment, the thickness of each layer within the stack of nanosheets may range from 5 nm to 20 nm.

To pattern the structure, a mask layer (not shown) may be formed atop the stack of nanosheets. In some examples, a hardmask may be used for patterning the stack of nanosheets. In some embodiments, the hardmask may have the composition of a nitride, such as silicon nitride. For example, a pattern (not shown) is produced by applying a photoresist to the surface to be etched; exposing the photoresist to a pattern of radiation; and then developing the pattern into the photoresist utilizing conventional resist developer. Once the patterning of the photoresist is completed, the sections of the nanosheet stack covered by the photoresist are protected while the exposed regions are removed using a selective etching process that removes the unprotected regions. The etch process may include a direction etch process, such as reactive ion etching (RIE).

FIG. 6 also illustrates an embodiment of forming a replacement gate structure 15. By “replacement”, e.g., as used to describe the replacement gate structure 15, it is meant that the structure is present during processing of the semiconductor device, but is removed from the semiconductor device prior to the device being completed. As used herein, the term “replacement gate structure” denotes a sacrificial structure that dictates the geometry and location of the later formed functioning gate structure. The “functional gate structure” operates to switch the semiconductor device from an “on” to “off” state, and vice versa.

In an embodiment, the sacrificial material that provides the replacement gate structure 15 may be composed of any material that can be etched selectively to the stack of nanosheets 11. In an embodiment, the sacrificial material of the replacement gate structure 15 may be composed of a silicon-including material, such as polysilicon. In another embodiment, the sacrificial material of the replacement gate structure 15 may be composed of a dielectric material, such as an oxide or amorphous carbon. The replacement gate structure 15 may be formed using deposition (e.g., chemical vapor deposition) photolithography and etch processes (e.g., reactive ion etching). In some embodiments, a mask structure 14 may be employed. The mask structure 14 may be provided using deposition and photolithography steps, and may be employed in combinations with the directional, i.e., anisotropic, etch processes to shape the geometry of the replacement gate structure 15 that is composed of the sacrificial material. Using the mask structure 14, the sacrificial material that provides the replacement gate structure 15 may be etched to provide the gate geometry in accordance with the mask structure 14 using a directional etch process, such as reactive ion etching (RIE).

FIG. 6 also illustrates an embodiment of removing the second sacrificial nanosheet and replacing it with a dielectric material to provide the self-aligned substrate isolation layer 9. In an embodiment, the second sacrificial nanosheets is a silicon germanium having a high germanium content, e.g., 55% germanium within the silicon germanium material. In an embodiment, the second sacrificial nanosheets may be removed by an isotropic etch, e.g., non-directional etch, such as a gas etch, or plasma etch. In some embodiments, the etch process for removing the second sacrificial nanosheets is selective to the material layers that are processed to provide the nanosheets 11 for the channel regions of the semiconductor devices. As used herein, the term “selective” in reference to a material removal process denotes that the rate of material removal for a first material is greater than the rate of removal for at least another material of the structure to which the material removal process is being applied. For example, in an embodiment, a selective etch may include an etch chemistry that removes a first material selectively to a second material by a ratio of 10:1 or greater, e.g., 1000:1. For example, the etch process may remove the silicon and germanium (SiGe) containing material having a germanium content of 55 wt. % of the second sacrificial nanosheet without removing the semiconductor material of silicon (Si) that provides the nanosheets 11 for the channel region, and/or without removing the layers composed silicon and germanium (SiGe) having a germanium (Ge) content of 30%, which may be other sacrificial layers that are removed in following process steps to suspend the nanosheets 11 for the channel regions.

The space provided by removing the first sacrificial nanosheet is filled with a dielectric material using deposition and etch back processes to provide the self-aligned substrate isolation layer 9. For example, the self-aligned substrate isolation layer 9 may be composed of a dielectric material, such as silicon nitride or silicon oxide, and may be formed using a deposition process, such as chemical vapor deposition (CVD) or atomic layer deposition (ALD).

The gate spacer 8 that is abutting the replacement gate structure 15 may be formed using deposition and etch back processes.

FIG. 6 also illustrates a nanosheet stack recess step, and an isotropic etch back of the sacrificial nanosheets 13 to form an indentation to form an inner spacer 12. The etch process for recessing the stack of nanosheets may be an anisotropic etch, such as reactive ion etching (RIE), and may be referred to as a nanostructure stack recess. Following the anisotropic etching to recess the fin stack, an isotropic etch, such as a plasma etch, may be performed to etch back the remaining sacrificial nanosheets 13 for forming the inner spacer 12. The inner spacer 12 may be formed by indenting the ends of the sacrificial nanosheets 13 relative to the nanosheets identified by reference number 11 in the patterned stacks. For example, the sacrificial nanosheets 13 may be composed of silicon germanium (SiGe30) layer having 30% germanium (Ge) content, i.e., low germanium (Ge) content silicon germanium (SiGe), which can be etched selectively to the nanosheets 11 of silicon that can be used for the channel regions in the final devices. Indentation may include an etch process that isotopically removes the low germanium (Ge) content silicon germanium (SiGe) relative to the silicon (Si) material of the nanosheets 11.

In a following step, the dielectric material for the inner spacer 12 may be conformally deposited using a chemical vapor deposition process (CVD) process, such as plasma enhanced chemical vapor deposition (PECVD) or metal organic chemical vapor deposition (MOCVD). In yet further embodiments, the dielectric material for the inner spacer 12 may be atomic layer deposition (ALD). The inner spacer 12 may be composed of a nitride or oxide material. For example, the inner spacer 12 may be composed of a nitride, such as silicon nitride, or the outer spacer may be composed of an oxide, such as silicon oxide. An etch back process may remove the portion of the dielectric layer extending outside of the recesses formed by indenting the first sacrificial nanosheets 62, in which the remaining portions of the dielectric filling the recesses provides the inner spacers 12.

FIG. 7 illustrates an embodiment of a placeholder cavity etch to form a placeholder cavity 85, and a deposition step for depositing a dielectric material to provide the first placeholder 1. The dielectric material may be deposited to fill the placeholder cavity 85, and recessed with an etch process. The dielectric fill height is selected to provide that first placeholder 1 contact at least one channel layer for the devices that are processed to provide low power consumption performance.

Forming the placeholder cavity 85 may employ an anisotropic etch, such as reactive ion etch. The anisotropic etch may employ the mask structure 14 of the replacement gate structure 15 and the gate sidewall spacer 8 as an etch mask for etching the placeholder cavity 85 into the upper semiconductor material 4 that is present between the stacks of nanosheets 11. Because the etch process for forming the placeholder cavity 85 employs the stacks of nanosheets 11 that provide the channel regions as an etch mask, placeholder cavity 85 is aligned with the source/drain regions 50. More particularly, the placeholder cavity 85 is filled with dielectric material to provide the first placeholder 1. Thereafter, the source/drain regions 50 are formed atop the first placeholder 1. In some embodiments, the first placeholder 1 is therefore self-aligned to the source/drain regions 50.

In some embodiments, prior to forming the placeholder cavity 85, a liner 54 of dielectric material may be deposited using a conformal deposition process, such as chemical vapor deposition, e.g., metal organic chemical vapor deposition or atomic layer deposition. The etch process may etch the base portion of the liner 54 in forming the placeholder cavity 85. The liner 54 may retain its vertically orientated sections that remain on the sidewalls of the patterned stacks of nanosheets 11, the inner spacers 12, and the gate sidewall spacers 8.

Still referring to FIG. 7, a dielectric fill may be deposited and recessed to provide the first placeholder 1. The dielectric fill is positioned to contact at least one nanosheet 11 in the channel regions. The nanosheets that are contacted by the dielectric fill are depopulated. Depopulated channel regions are suitable for low power consumption devices, such as the low power consumption field effect transistors that are depicted in FIGS. 4 and 5.

The dielectric fill for the first placeholder 1 may be deposited using a deposition process, such as chemical vapor deposition. The fill for the first placeholder 1 may be composed of any dielectric, such as an oxide or nitride, so long as the dielectric selected meets the requirements of etch selectivity in the process sequences described below. In some examples, the dielectric fill 1 may have a composition that is selected from SiO₂, SiN, SiBCN, SiC, SiOC, SiOCN, AlNₓ, AlOₓ and combinations thereof.

Following deposition, the fill for the first placeholder 1 may be recessed by an anisotropic etch, such as reactive ion etching (RIE). As noted, the height of the dielectric fill 1 following this recess step is selected to provide the number of nanosheets 11 that the dielectric fill 1 will contact. Each nanosheet 11 that is in contact with the first placeholder 1 will result in a depopulated channel.

The structures depicted in FIGS. 6 and 7 may provide initial structures for methods used in processing the semiconductor devices that have been described with reference to FIGS. 1-5. The first placeholders 1 that are illustrated in FIG. 7 may be selectively removed for applications used in high performance semiconductor devices, such as the high performance field effect transistors that are depicted in FIGS. 2 and 3.

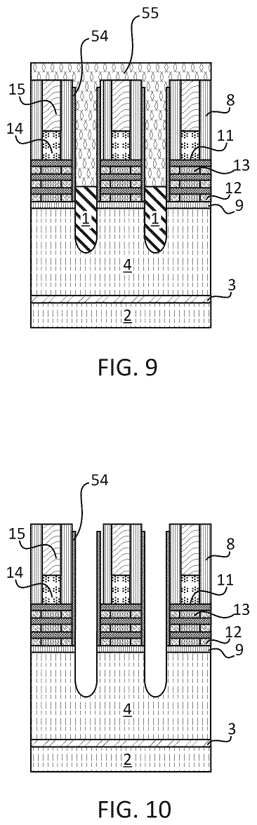

FIGS. 8 and 9 illustrate an embodiment of forming a mask 55, e.g., photoresist mask, which is used to protect the first placeholders 1 in regions of the device that are going to remain in the low power consumption devices, while removing exposed first placeholders 1 in regions of the structure that are going to be processed to provide high performance semiconductor devices. The mask 55 may be formed by a pattern that is produced by applying a photoresist to the surface to be etched, exposing the photoresist to a pattern of radiation, and then developing the pattern into the photoresist utilizing conventional resist developer. Once the patterning of the photoresist is completed, the first placeholders 1 covered by the photoresist are protected while the exposed first placeholders 1 are removed using an etching process. The etch process may include a direction etch process, such as reactive ion etching (RIE).

FIG. 8 illustrates an embodiment of a mask 55 that may be used in a process flow for forming a low power consumption semiconductor device with a backside contact 48, as depicted in FIG. 4. The mask 55 depicted in FIG. 8 protects one of the first placeholders 1 for providing a depopulated channel, while leaving one of the first placeholders 1 exposed so that it can be removed in processing to provide a backside contact 46. FIG. 9 illustrates an embodiment of a mask 55 that protects the first placeholders 1 in a process flow for forming the low power consumption semiconductor devices with frontside contacts 47 that are depicted in FIG. 5.

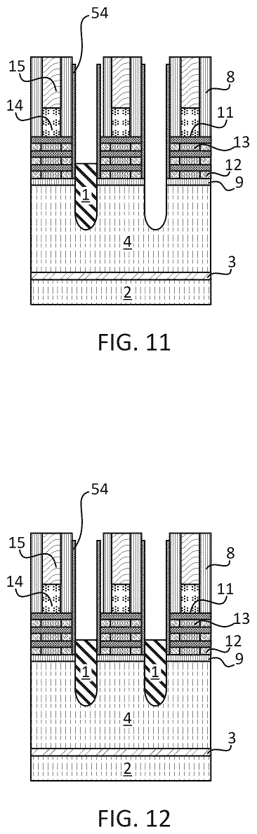

FIGS. 10, 11 and 12 illustrate an embodiment of removing the exposed first placeholders 1 using the etch mask 55 that is depicted in FIGS. 8 and 9. FIG. 10 illustrates removing the first placeholders 1 from each of the cavities in regions of the structure that are processed to provide high performance semiconductor devices, such as the devices depicted in FIGS. 2 and 3. FIG. 11 illustrates the resultant structure in which the etch mask 55 depicted in FIG. 8 is employed to protect one of the first placeholders 1 from being removed, while an exposed first placeholder 1 is removed. FIG. 11 illustrates a process step for forming the low power consumption semiconductor device depicted in FIG. 4.

FIG. 12 illustrates removing the etch mask 55 that is depicted in FIG. 9. FIG. 12 illustrates a process step for forming the low power consumption semiconductor devices depicted in FIG. 5. FIG. 12 illustrates a structure in which the first placeholders 1 are not removed. This type of device is eventually processed to include frontside contacts 47 to the source/drain regions 50. In some embodiments, an oxygen ashing process is used to remove mask 55.

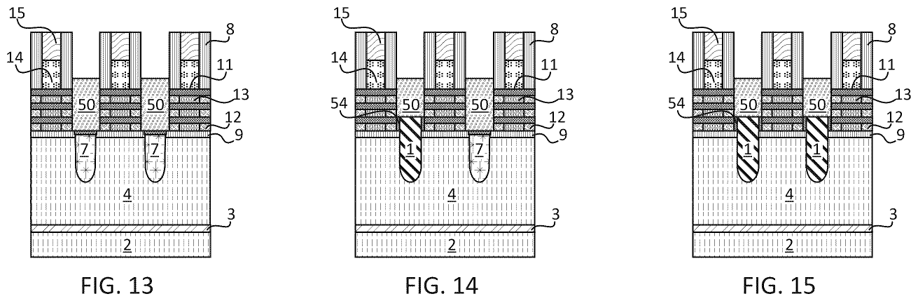

FIGS. 13-15 illustrate forming the epitaxially grown material that provides the second placeholder 7 in FIGS. 2, 3 and 4. The second placeholder 7 is formed by epitaxially growing a semiconductor composition material in the placeholder cavity 85 from which the first placeholder 1 was removed, as described above with reference to FIGS. 10-12. For example, the second placeholder 7 may be composed of silicon and germanium containing material, such as silicon germanium. The second placeholder 7 that is deposited in FIGS. 13-15 can be different in composition than the dielectric composition of the first placeholder 1. Following formation, the second placeholder 7 may be recessed to provide that the height to the second placeholder 7 does not reach the nanosheets 11 that provide channel regions for the field effect transistors. The second placeholder 7 is composed of a composition material that may be used in a process sequence for forming backside contacts 46 to the source/drain regions 50.

Still referring to FIGS. 13-15, following the formation of second placeholder 7, the source/drain regions 50 may be formed. The source/drain regions 50 may be formed by an epitaxial deposition method. In some embodiments, the source/drain regions 50 are comprised of an epitaxial semiconductor material. The source/drain regions 50 may have the composition of an epitaxial semiconductor material that is doped to an n-type or p-type dopant. In some embodiments, the epitaxial semiconductor material that provides the source/drain regions 50 may have a composition that includes silicon (Si), germanium (Ge), silicon germanium (SiGe), silicon doped with carbon (Si:C), or the epitaxial semiconductor material that provides the source and drain regions may have a composition that includes a type III-V compound semiconductor, such as gallium arsenide (GaAs). The epitaxial semiconductor material for the source/drain regions 50 may be in situ doped to a p-type or n-type conductivity.

At this stage of the process flow, the structure depicted in FIG. 13 may be employed in a process sequence for forming either of the devices depicted in FIGS. 2 and 3. The structure depicted in FIG. 14 may be employed in a process sequence for forming the device depicted in FIG. 4, and the structure depicted in FIG. 15 may be employed in a process sequence for forming the device depicted in FIG. 5.

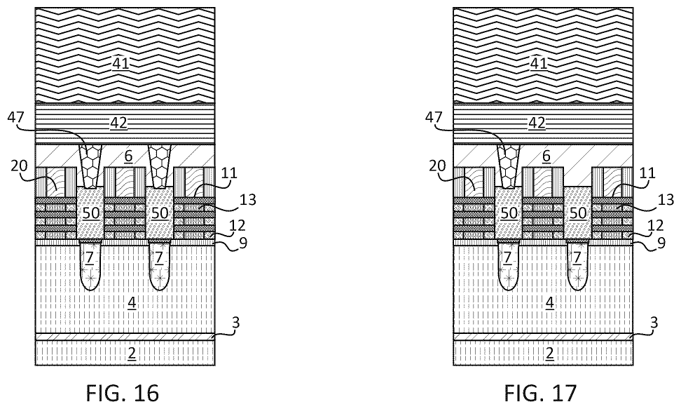

FIGS. 16, 17, 18 and 19 depict replacing the replacement gate structure 15 with a gate structure 20 that is functional as part of a replacement gate process. First, an interlevel dielectric layer 6 is deposited which is then etched or planarized to expose an upper surface of the mask structure 14 that is present over the replacement gate structure 15. The replacement gate structure 15 may then be removed. The mask structure 14 and replacement gate structure 15 may be removed using a selective etch process. In some embodiments, once the replacement gate structure 15 is removed, the remaining potions of the sacrificial nanosheets 13 are removed by an etch selective to the nanosheets 11 that provide the channel regions. Suspension of the nanosheets 11 may be provided by the inner spacers 12. A gate structure 20 that is functional can then be formed in the openings to the channel regions provided by the nanosheets 11 that are exposed by removing the replacement gate structure 15.

The method can continue with the forming a gate structure 20 that is functional in the space that was created by removing the replacement gate structure 15. In some embodiments, the gate structure 20 that is functional includes a gate dielectric and a metal gate conductor. The gate dielectric may be a high-k dielectric material, such as hafnium oxide (HfO₂). The gate dielectric for the gate all around structure may be deposited using chemical vapor deposition (CVD) or atomic layer deposition (ALD) and is present on the entirety of the exterior surfaces of the nanosheets 11. The metal gate conductor for the gate structure 20 may encapsulate the nanosheets 11 including the gate dielectric present on the exterior surfaces of the nanosheets 11. The gate conductor may have the composition of a metal, such as tungsten (W) or an n-type or p-type work function metal, e.g., titanium nitride.

FIGS. 16-19 also depict an embodiment of forming middle of the line (MOL) processing that provides the frontside contacts 47, back end of the line (BEOL) metal lines processing, and bonding a carrier wafer 41. The frontside contacts 47 extend from metallization in the back end of the line (BEOL) processing level 42 to the source/drain regions 50. Some of these contacts may be formed in via openings that are formed into the interlevel dielectric layer 6. The openings may be formed using photolithography to provide an etch mask followed by anisotropic etching, e.g., reactive ion etching. Thereafter, the openings are then filled with an electrically conductive material, such as a metal, e.g., copper, to provide vias. Thereafter, a deposition, pattern and fill sequence is repeated to forms lines.

The back end of the line (BEOL) processing level 42 includes metal lines and vias (metallization) that may be in electrical communication with the frontside contacts 47 produced during the middle of the line (MOL) processing. The process sequence that is used for forming the metal lines and vias is a back end of the line (BEOL) process. The carrier wafer 41 provides support to the structure, as the backside of the device is processed.

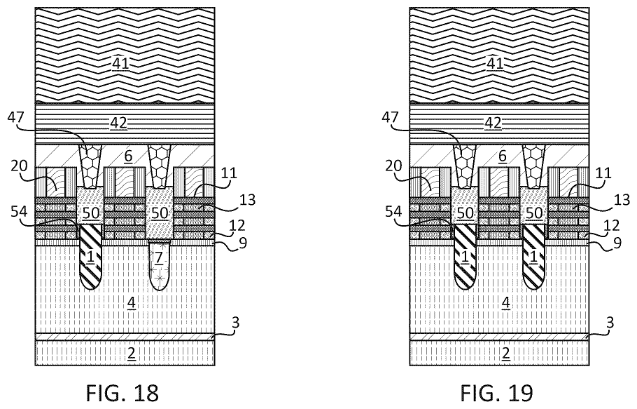

At this stage of the process flow, the structure depicted in FIG. 16 may be employed in a process sequence for forming the high performance semiconductor devices depicted in FIG. 2. The structure depicted in FIG. 17 may be used in a process sequence for forming the high performance semiconductor devices depicted in FIG. 3. The structure depicted in FIG. 18 may be used in a process sequence for forming the low power consumption semiconductor devices depicted in FIG. 4. At this stage of the process flow, the structure depicted in FIG. 19 may be used in a process sequence for forming the devices depicted in FIG. 5.

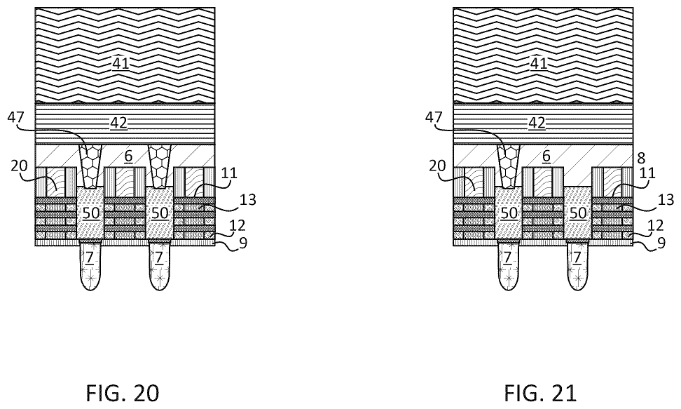

FIGS. 20-23 illustrate an embodiment of removal of the structure that includes the substrate 2, the etch layer 3 and remaining portions of the upper semiconductor layer 4. These elements may be removed by selective etching. For example, the remaining portions of the upper semiconductor layer 4 may then be removed by an etch process that is selective to first placeholders 1 and the second placeholders 7.

In some embodiments, the etch process steps for removing the upper semiconductor layer 4 selectively to the dielectric fill for the first placeholder 1 and the semiconductor fill for the second placeholder 7 may have a higher degree of selectivity for the dielectric fill of the first placeholder 1 than for the fill of the second placeholder 7. For that reason, during the etch process step for removing the upper semiconductor layer 4, the dimensions of the second placeholder 7 may be reduced. This provides that the second placeholder 7 has a lesser width than the first placeholder 1.

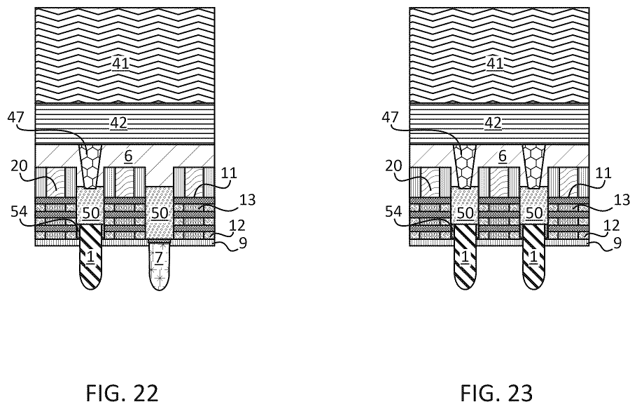

At this stage of the process flow, the structure depicted in FIG. 20 may be employed in a process sequence for forming the high performance semiconductor devices depicted in FIG. 2. The structure depicted in FIG. 21 may be used in a process sequence for forming the high performance semiconductor devices depicted in FIG. 3. The structure depicted in FIG. 22 may be used in a process sequence for forming the low power consumption semiconductor devices depicted in FIG. 4. The structure depicted in FIG. 23 may be used in a process sequence for forming the low power consumption semiconductor devices depicted in FIG. 5.

Thereafter, a backside interlevel dielectric layer 51 may be deposited following a planarization process. The backside interlevel dielectric layer 51 is similar to the upper interlevel dielectric layer 6.

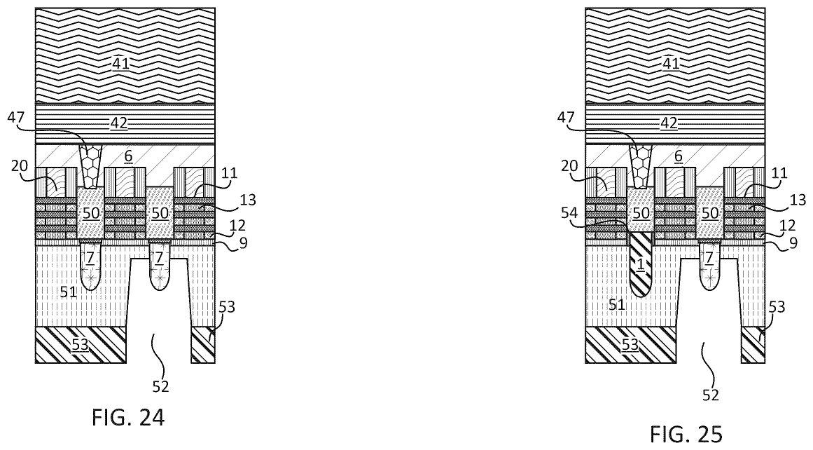

FIGS. 24 and 25 illustrate some embodiments of forming backside contacts 48 for the structures depicted in FIGS. 3 and 4. In some examples, forming the backside contacts 48 can include sacrificial placeholder removal, e.g., removal of exposed portions of the second placeholder 7, an optional source and drain gouging step (etch process), a pre-silicide clean, and back side contact metallization and planarization, e.g., chemical mechanical planarization.

More particularly, the high performance semiconductor device that is depicted in FIG. 3 includes a backside contact 46. More particularly, the low power consumption semiconductor device that is depicted in FIG. 4 includes a backside contact 46. The high performance semiconductor device depicted in FIG. 2 only includes frontside contacts 47. The low power consumption semiconductor device depicted in FIG. 5 only includes frontside contacts 47.

First, an etch mask 53 is formed on the backside interlevel dielectric layer 51. The etch mask 53 may be a photoresist mask that is formed using photolithography. The etch mask 53 has openings that are positioned to overly only the second placeholder 7 that is underlying the source/drain regions 50 that do not include, i.e., are not in direct contact with, a frontside contact 47. The first placeholders 1 and second placeholders 7 that are underlying source/drain region 50 that are contacted by the frontside contacts 47 are not exposed by the etch mask 53.

Following formation of the etch mask 53, the backside interlevel dielectric layer 51 is etched to expose the second placeholder 7 for the source/drain regions 50 that are not contacted by the frontside contacts 47.

Referring back to FIGS. 24 and 25, the backside contact placeholder, which is provided by the second placeholder 7, is then removed using an etch process, which may be selective to the source/drain regions 50. Thereafter, the backside contact 46 may be formed within the opening created by removing the backside contact placeholder, e.g., second placeholder 7. The backside contact 46 may be formed in direct contact with the backside surface of the source/drain regions 50.

FIGS. 24 and 25 depict an embodiment of removing the exposed second placeholders 7 and an optional step of gauging the backside of the epitaxial semiconductor material that provides the source/drain regions 50. In some embodiments, the exposed second placeholder 7 is removed using an etch process, which may be selective to the source and drain regions 50. In a following step, the exposed portion of the source/drain regions 50 that are exposed by removing the placeholder fill 7 can then be etched. Gouging the backside surface of the source and drain regions 50 can increase the contact surface area between the backside contact 48 and the source/drain regions 50.

Thereafter, the backside contacts 48 may be formed within the opening created by removing the exposed second placeholders 7. The backside contact 48 may be formed in direct contact with the backside surface of the source/drain regions 50. The backside contacts 48 may have the composition of a metal, such as copper, aluminum, platinum, silver, gold, tungsten, and alloys or combinations thereof. The backside contacts 46 may be deposited using plating and/or physical vapor deposition (PVD). Following deposition, a planarization process may be performed, such as chemical mechanical planarization (CMP).

Referring to FIGS. 1-5, at least one of the source/drain regions 50 may be connected to the power rail 44 by a backside contact 46. The power rail 44 is in electrical communication with a backside power distribution network 43.

FIGS. 1-5 depict forming the backside power rail 44. In some embodiments, an interlevel dielectric layer is first deposited and then etched to form openings. Thereafter, the openings are then filled with a conductive material, such as a metal, e.g., copper, to provide the backside power rail 44.

Thereafter, a deposition, pattern and fill sequence is repeated to forms lines in backside power distribution network 43. This may be formed using a single damascene method for forming lines and vias. However, dual damascene sequences are also applicable. The sequence of deposition, pattern and etch are repeated as many times as needed to form each level of metal lines and vias.

Reference in the specification to “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

Having described preferred embodiments of a methods and structures for channel depopulation using placeholder dielectric are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device comprising:
first stacked channel layers;
second stacked channel layers; and
a placeholder disposed between the first stacked channel layers and the second stacked channel layers, wherein sidewalls of the placeholder directly contact sidewalls of at least one channel in the first stacked channel layers and at least one channel in the second stacked channel layers.

2. The semiconductor device of claim 1, wherein the placeholder includes a dielectric core having a liner present on exterior surfaces.

3. The semiconductor device of claim 2, wherein the liner has a composition selected from the group consisting of SiN, SiBCN, SiC, SiOC, SiOCN, AlNx, AlOx and combinations thereof.

4. The semiconductor device of claim 1 further comprising:
a source/drain region atop the placeholder to each of the first channels and the second stacked channels.

5. The semiconductor device of claim 1, wherein at least one of the first stacked channel layers and the second stacked channel layers includes nanosheet layers.

6. A semiconductor device comprising:
a source/drain region disposed between vertically stacked channel regions; and
a placeholder disposed within a portion of the source/drain region and interposed between at least one channel region and the source/drain region.

7. The semiconductor device of claim 6, wherein the placeholder includes a dielectric core having a liner present on exterior surfaces.

8. The semiconductor device of claim 7, wherein the liner has a composition selected from the group consisting of SiN, SiBCN, SiC, SiOC, SiOCN, AlNₓ, AlOₓ and combinations thereof.

9. The semiconductor device of claim 6, wherein the vertically stacked channel regions include nanosheets.

10. The semiconductor device of claim 6, wherein a gate structure is present on vertically stacked channel regions.

11. The semiconductor device of claim 10, wherein the gate structure is a gate all around gate structure.

12. A semiconductor device comprising:
a first semiconductor device including first stacked channel layers;
a second semiconductor device including second stacked channel layers;
a first placeholder disposed adjacent to the first stacked channel layers; and
a second placeholder disposed adjacent to the second stacked channel layers, wherein a height of the first placeholder is greater than a height of the second placeholder to provide that the first placeholder contacts at least one first channel layer in the first stacked channel layers.

13. The semiconductor device of claim 12, wherein the first placeholder has a different composition than the second placeholder.

14. The semiconductor device of claim 12, wherein the first placeholder includes a dielectric core.

15. The semiconductor device of claim 14, wherein the first placeholder includes a dielectric liner present on exterior surfaces of the dielectric core.

16. The semiconductor device of claim 12, wherein the second placeholder includes an intrinsic semiconductor material.

17. The semiconductor device of claim 12, wherein the second placeholder has a smaller width than the first placeholder.

18. The semiconductor device of claim 12, wherein the second placeholder does not extend to a height that contacts at least one second channel layer in the second stacked channel layers.

19. The semiconductor device of claim 12 including source/drain regions atop the placeholder to each of the first stacked channel layers and the second stacked channel layers.

20. The semiconductor device of claim 12, wherein at least one of the first stacked channel layers and the second stacked channel layers is a nanosheet.
